(19) United States
(12) Patent Application Publication
(10) Pub. No.: US 2026/0063701 A1
(43) Pub. Date: Mar. 5, 2026

(54) DETECTION METHOD OF MOS TRANSISTOR

(71) Applicant: United Microelectronics Corp., Hsinchu (TW)

(72) Inventors: Zhi Sheng Chen, Tainan City (TW); Ying-Ting Kuo, Tainan City (TW)

(73) Assignee: United Microelectronics Corp., Hsinchu (TW)

(21) Appl. No.: 18/885,772

(22) Filed: Sep. 16, 2024

(30) Foreign Application Priority Data
Sep. 2, 2024 (TW) 113133122

(51) Int. Cl. G01R 31/265; H01L 29/08; H01L 29/161; H01L 29/78

(52) U.S. Cl. CPC G01R 31/2653; H10D 30/601; H10D 62/151; H10D 62/832

(57) ABSTRACT

A detection method of a metal-oxide-semiconductor (MOS) transistor is provided. The detection method includes the following steps. A MOS transistor is provided, wherein a source and a drain of the MOS transistor are each connected to a contact. The contacts are removed to form contact holes exposing the source and the drain. The source and the drain are removed through the contact holes to form recesses. The contact holes and the recesses are filled with a protective material. The cross-sectional profiles of the recesses are obtained. It is determined whether the MOS transistor is failed according to the cross-sectional profiles of the recesses.

### CROSS-REFERENCE TO RELATED APPLICATION

This application claims the priority benefit of Taiwan application serial no. 113133122, filed on Sep. 2, 2024. The entirety of the above-mentioned patent application is hereby incorporated by reference herein and made a part of this specification.

### BACKGROUND

### Technical Field

The present invention relates to a detection method of a semiconductor structure, and in particular to a detection method of a metal-oxide-semiconductor (MOS) transistor.

### Description of Related Art

In the current semiconductor technology, after the MOS transistor is formed, a detection step is performed to determine whether the MOS transistor is failed. For example, through the detection step, it can be known whether the position of the lightly doped drain (LDD) region of the MOS transistor shifts, causing the transistor to be failed.

Generally speaking, after forming the MOS transistor, the transistor is cut along the channel direction to make a sample. Then, the sample is placed in the etching solution to remove the source/drain structure formed by the doped region as the LDD region and the SiGe layer to form a recess. After that, a transmission electron microscopy (TEM) analysis is performed to determine whether the transistor is failed through the ross-sectional profile of the recess.

However, after cutting the transistor and placing the sample into the etching solution, the etching solution not only removes the source/drain structure, but also etches the substrate around the source/drain structure, causing the profile of the formed recess to change and thus cannot accurately correspond to the profile of the source/drain structure. As a result, it is impossible to accurately determine whether the transistor is failed through the cross-sectional profile of the recess.

### SUMMARY

The present invention provides a detection method of a MOS transistor, which may quickly and accurately determine whether the MOS transistor is failed.

The detection method of the MOS transistor of the present invention includes the following steps. A MOS transistor is provided, wherein a source and a drain of the MOS transistor are each connected to a contact. The contacts are removed to form contact holes exposing the source and the drain. The source and the drain are removed through the contact holes to form recesses. The contact holes and the recesses are filled with a protective material. The cross-sectional profiles of the recesses are obtained. It is determined whether the MOS transistor is failed according to the cross-sectional profiles of the recesses.

In an embodiment of the detection method of the present invention, a method for obtaining the cross-sectional profiles of the recesses includes cutting the MOS transistor in a channel direction of the MOS transistor.

In an embodiment of the detection method of the present invention, the source and the drain include a semiconductor layer.

In an embodiment of the detection method of the present invention, the semiconductor layer includes a SiGe layer.

In an embodiment of the detection method of the present invention, in the cross-sectional profile of the recess, a width of a top and a width of a bottom are less than a width of a middle part.

In an embodiment of the detection method of the present invention, the source and the drain comprise a semiconductor layer and a doped region located around an upper portion of the semiconductor layer and extending below a gate of the MOS transistor.

In an embodiment of the detection method of the present invention, the semiconductor layer includes a SiGe layer.

In an embodiment of the detection method of the present invention, in the cross-sectional profile of the recess, a width of a top is greater than a width of a middle part, and the width of the middle part is greater than a width of a bottom.

In an embodiment of the detection method of the present invention, obtaining the cross-sectional profile of the recess includes using a transmission electron microscopy to obtain an image of the cross-sectional profile of the recess.

In an embodiment of the detection method of the present invention, the profile of the recess has a left-right symmetrical shape, and therefore the MOS transistor is determined to be not failed.

In an embodiment of the detection method of the present invention, the profile of the recess has a left-right asymmetric shape, and therefore the MOS transistor is determined to be failed.

In an embodiment of the detection method of the present invention, a method for removing the source and the drain includes performing a wet etching process through the contact holes.

In an embodiment of the detection method of the present invention, an etchant used in the wet etching process is dropped into the contact holes to provide the etchant to the source and the drain.

In an embodiment of the detection method of the present invention, the etchant includes a mix solution of hydrofluoric acid, nitric acid acetic acid.

In an embodiment of the detection method of the present invention, a mix ratio of hydrofluoric acid, nitric acid and acetic acid in the etchant is 1:3:8˜20.

In an embodiment of the detection method of the present invention, the protective material includes carbon, platinum, tungsten or silicon oxide.

Based on the above, in the detection method of the MOS transistor of the present invention, a wet etching process is performed to remove the source/drain structure through the contact hole formed by removing the contact. Therefore, the wet etching process may be easily controlled without causing serious damage to the substrate, so that the profile of the recess formed after removing the source/drain structure may accurately correspond to the profile of the source/drain structure. In this way, whether the MOS transistor is failed may be quickly and accurately determined based on the cross-sectional profile of the recess.

### BRIEF DESCRIPTION OF THE DRAWINGS

FIGS. 1A to 1D are schematic cross-sectional views of a detection method of a MOS transistor according to an embodiment of the present invention.

FIG. 2 is a schematic cross-sectional view of a sample of the TEM analysis of a failed MOS transistor.

FIG. 3 is a schematic cross-sectional view of a sample of the TEM analysis of a MOS transistor according to another embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing”and “having”are all open-ended terms, i.e., meaning “including but not limited to”.

In addition, the directional terms, such as “on”, “above”, “under” and “below” mentioned in the text are only used to refer to the direction of the drawings, and are not used to limit the present invention. Therefore, it should be understood that “on” may be used interchangeably with “under”. When a device such as a layer or a film is placed “on” another device, the device may be placed directly on the other device, or an intermediate device may be present. On the other hand, when a device is placed “directly on” another device, there is no intermediate device between the two.

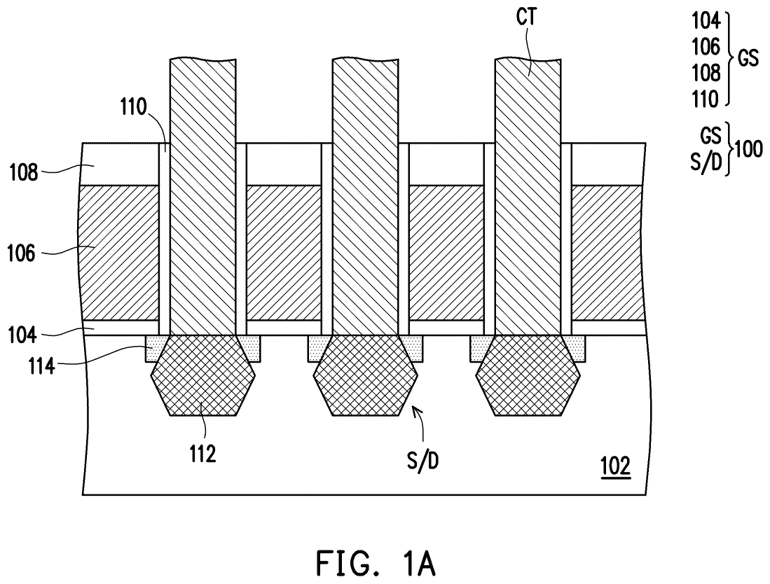

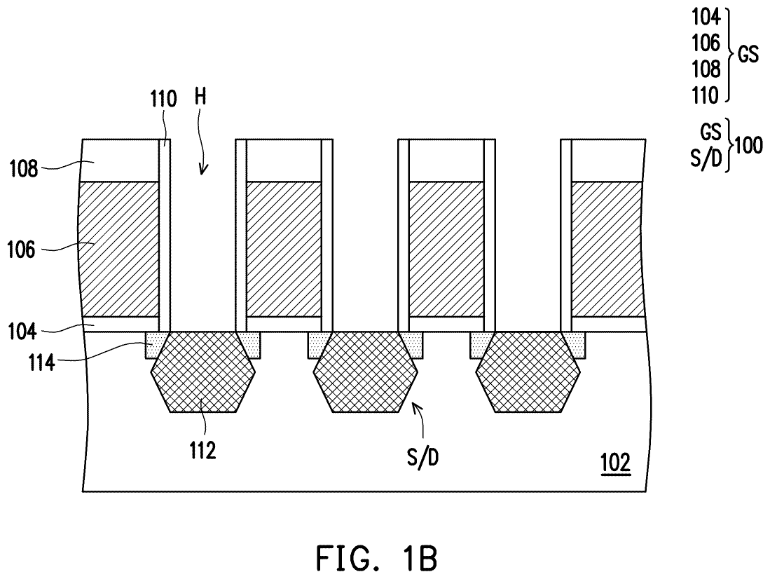

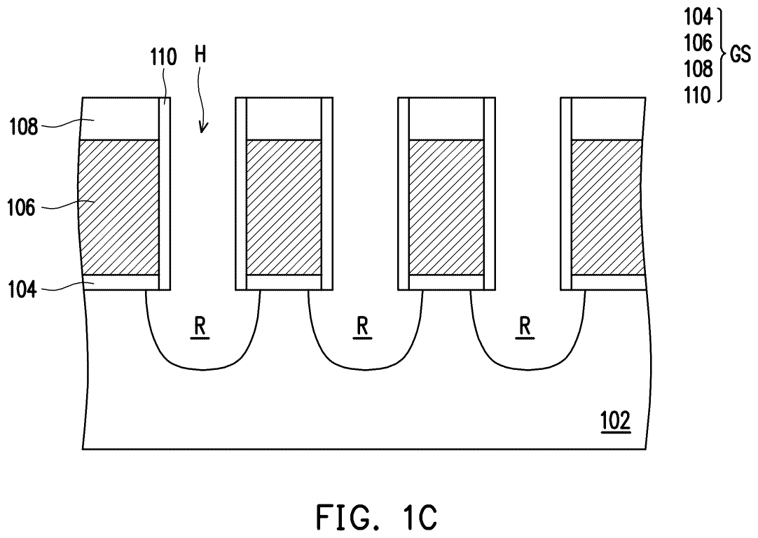

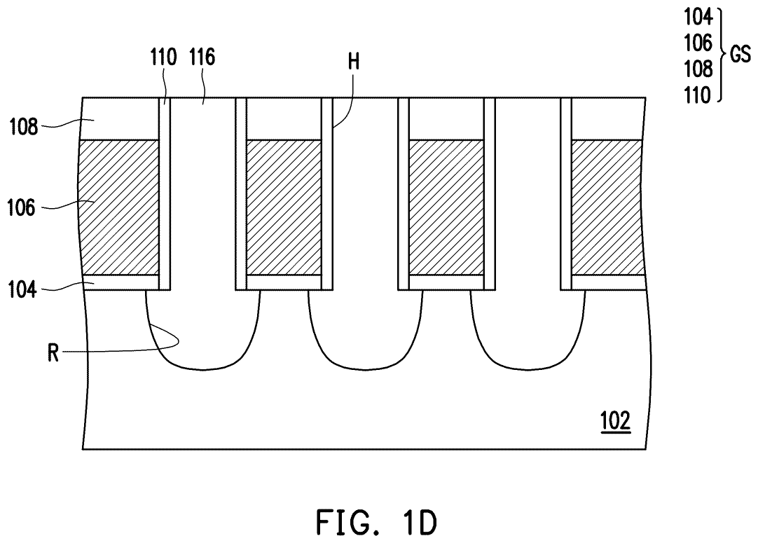

FIGS. 1A to 1D are schematic cross-sectional views of a detection method of a MOS transistor according to an embodiment of the present invention.

Referring to FIG. 1A, a MOS transistor 100 is provided. The MOS transistor 100 includes a gate structure GS and source/drain structures S/D located in a substrate 102 on opposite sides of the gate structure GS. The gate structure GS includes a gate dielectric layer 104 disposed on the substrate 102, a gate 106 disposed on gate dielectric layer 104, a capping layer 108 disposed on the gate 106 and a spacer 110 disposed on the sidewalls of the gate 106. In other embodiments, the gate structure of the MOS transistor may have other configurations, and the present invention does not limit this.

The source/drain structure S/D includes a semiconductor layer 112 disposed in the substrate 102 and a doped region 114 located around an upper portion of the semiconductor layer 112 and extending below the gate 106. The semiconductor layer 112 is, for example, a SiGe layer. The forming method of the semiconductor layer 112 may include the following steps. A recess is formed in the substrate 102. Then, a semiconductor material is epitaxially grown in the recess. Based on the characteristics of the epitaxial growth, the formed semiconductor layer 112 may have a diamond-shaped profile in which the width of the top and the width of the bottom are less than the width of the middle part. The doped region 114 may be used as the LDD region of the MOS transistor 100. In the present embodiment, after forming the semiconductor layer 112, an ion implantation process is performed to form the doped region 114. Additionally, the source/drain structure S/D is connected to a contact CT.

After performing the ion implantation process to form the doped region 114, the doped region 114 may not be formed at the correct position due to various process conditions. For example, the position of the doped region 114 may be shifted, or the doped region 114 may not be formed in the predetermined region. As a result, the MOS transistor 100 is seriously affected, and thus the MOS transistor 100 is failed. In addition, if the semiconductor layer 112 is not formed at the correct position, it may also cause the MOS transistor 100 to be failed. Therefore, a detection step needs to be performed on the MOS transistor 100 to confirm whether the doped region 114 and/or the semiconductor layer 112 are accurately formed in the correct region.

Referring to FIG. 1B, the contact CT is removed to form a contact hole H exposing the source/drain structure S/D. In the present embodiment, a wet etching process is performed to remove the contact CT. The etchant used in the wet etching process may be a mix solution of hydrogen peroxide (H₂O₂) and ammonium hydrogen oxide (NH₄OH). In an embodiment, hydrogen peroxide and ammonium hydroxide may be mixed in a ratio of 1:1, but the present invention is not limited thereto. The wet etching process may only remove the contact CT without causing serious damage to the source/drain structure S/D.

Referring to FIG. 1C, the source/drain structure S/D is removed through the contact hole H to form a recess R. In the present embodiment, a wet etching process is performed in which the etchant is dropped into the contact hole H to provide the etchant to the source/drain structure S/D. In this way, the etchant may only etch the source/drain structure S/D and slightly etch the surrounding substrate 102, without causing serious damage to the substrate 102. Therefore, the profile of the formed recess R may accurately correspond to the profile of the source/drain structure S/D.

Furthermore, in the present embodiment, the source/drain structure S/D includes the semiconductor layer 112 and the doped region 114 located around the upper portion of the semiconductor layer 112 and extending below the gate 106. Depending on the material characteristics of the semiconductor layer 112 and the doped region 114, after the wet etching process, the recess R is formed with the width of the top being greater than the width of the middle part and the width of the middle part being greater than the width of the bottom, and the sidewall and bottom surface of the recess R are curved surfaces.

The etchant used in the wet etching process may be a mix solution of hydrofluoric acid, nitric acid and acetic acid, and a mix ratio of hydrofluoric acid, nitric acid and acetic acid may be 1:3:8˜20. In an embodiment, hydrofluoric acid, nitric acid and acetic acid may be made into a mix solution in a ratio of 1:3:15, but the present invention is not limited thereto.

Referring to FIG. 1D, a protective material 116 is filled in the contact hole H and the recess R. In the present embodiment, carbon, platinum, tungsten or silicon oxide may be used as the protective material 116, but the present invention is not limited thereto. The protective material 116 may prevent the substrate 102 from being damaged in the subsequent TEM analysis, and thus prevent the profile of the recess R from being changed.

After that, the MOS transistor 100 is cut in the channel direction of the MOS transistor 100 to obtain a sample required for the subsequent TEM analysis. Then, a TEM analysis is performed on the sample to obtain a cross-sectional profile of the recess R. In the present embodiment, through the TEM analysis, an image of the cross-sectional profile of the recess R may be obtained. Then, based on the obtained cross-sectional profile of the recess R, it is determined whether the MOS transistor 100 is failed.

For example, in the MOS transistor 100, when the source/drain structure S/D is formed in the correct region, that is, the position of the semiconductor layer 112 and the position of the doped region 114 are not shifted, from the image of the cross-sectional profile of the recess R, it can be clearly seen that the cross-sectional profile of the recess R is U-shaped in which the width of the top is greater than the width of the middle part and the width of the middle part is greater than the width of the bottom, and the cross-sectional profile of the recess R has a left-right symmetrical shape. In this way, it may be determined that the MOS transistor 100 is not failed.

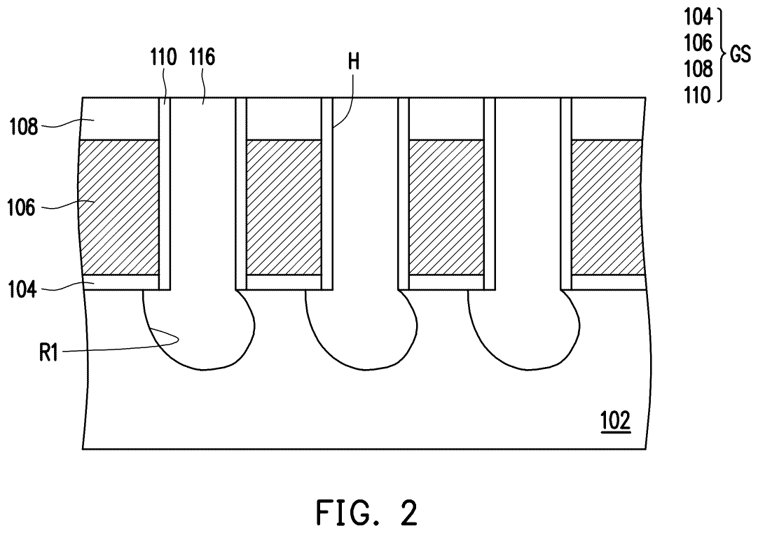

On the contrary, when the source/drain structure S/D is not formed in the correct region, that is, the position of the semiconductor layer 112 and/or the position of the doped region 114 are shifted, from the image of the cross-sectional profile of the recess R, it can be clearly seen that the cross-sectional profile of the recess R has a left-right asymmetrical shape. Therefore, the MOS transistor 100 is determined to be failed. For example, as shown in FIG. 2, when the position of the doped region 114 is shifted, the formed recess R1 has a left-right asymmetric profile. Therefore, by analyzing the image of the cross-sectional profile of the recess R1 by the TEM, it may be quickly and accurately determined that the MOS transistor 100 is failed.

Based on the above, in the detection method of the MOS transistor of the present invention, a wet etching process is performed to remove the source/drain structure through the contact hole formed by removing the contact. Therefore, the wet etching process may be easily controlled without causing serious damage to the substrate, so that the profile of the recess formed after removing the source/drain structure may accurately correspond to the profile of the source/drain structure. In this way, whether the MOS transistor is failed may be quickly and accurately determined based on the cross-sectional profile of the recess.

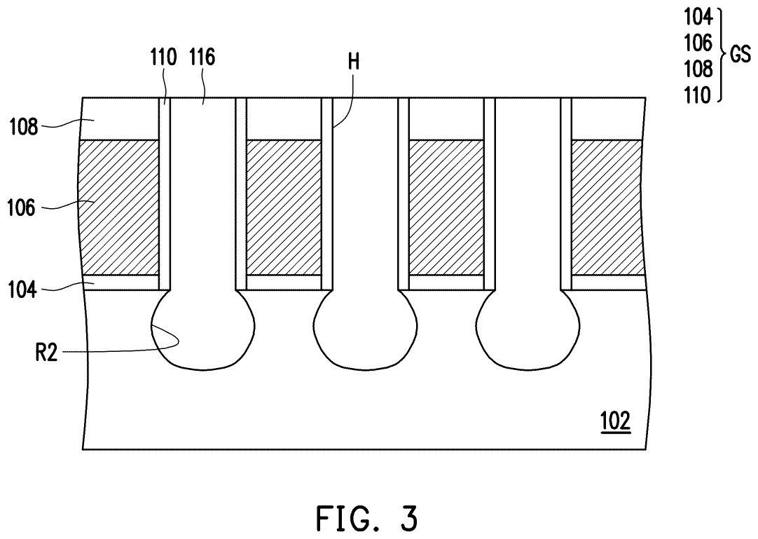

In the embodiment where source/drain structure S/D only includes the semiconductor layer 112, as shown in FIG. 3, after removing the source/drain structure S/D, the cross-sectional profile of the recess R2 is diamond-shaped in which the width of the top and the width of the bottom are less than the width of the middle part, and the sidewall and the bottom surface of the recess R2 are curved surfaces. Therefore, in the same manner as in the previous embodiment, whether the MOS transistor is failed may be quickly and accurately determined based on the cross-sectional profile of the recess R2.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A detection method of a metal-oxide-semiconductor (MOS) transistor, comprising:
providing a MOS transistor, wherein a source and a drain of the MOS transistor are each connected to a contact;
removing the contacts to form contact holes exposing the source and the drain;
removing the source and the drain through the contact holes to form recesses;
filling the contact holes and the recesses with a protective material;
obtaining cross-sectional profiles of the recesses; and
determining whether the MOS transistor is failed according to the cross-sectional profiles of the recesses.

2. The detection method of claim 1, wherein a method for obtaining the cross-sectional profiles of the recesses comprises cutting the MOS transistor in a channel direction of the MOS transistor.

3. The detection method of claim 2, wherein the source and the drain comprise a semiconductor layer.

4. The detection method of claim 3, wherein the semiconductor layer comprises a SiGe layer.

5. The detection method of claim 3, wherein in the cross-sectional profile of the recess, a width of a top and a width of a bottom are less than a width of a middle part.

6. The detection method of claim 2, wherein the source and the drain comprise a semiconductor layer and a doped region located around an upper portion of the semiconductor layer and extending below a gate of the MOS transistor.

7. The detection method of claim 6, wherein the semiconductor layer comprises a SiGe layer.

8. The detection method of claim 6, wherein in the cross-sectional profile of the recess, a width of a top is greater than a width of a middle part, and the width of the middle part is greater than a width of a bottom.

9. The detection method of claim 2, wherein obtaining the cross-sectional profile of the recess comprises using a transmission electron microscopy to obtain an image of the cross-sectional profile of the recess.

10. The detection method of claim 1, wherein the profile of the recess has a left-right symmetrical shape, and therefore the MOS transistor is determined to be not failed.

11. The detection method of claim 1, wherein the profile of the recess has a left-right asymmetric shape, and therefore the MOS transistor is determined to be failed.

12. The detection method of claim 1, wherein a method for removing the source and the drain comprises performing a wet etching process through the contact holes.

13. The detection method of claim 12, wherein an etchant used in the wet etching process is dropped into the contact holes to provide the etchant to the source and the drain.

14. The detection method of claim 13, wherein the etchant comprises a mix solution of hydrofluoric acid, nitric acid acetic acid.

15. The detection method of claim 14, wherein a mix ratio of hydrofluoric acid, nitric acid and acetic acid in the etchant is 1:3:8˜20.

16. The detection method of claim 1, wherein the protective material comprises carbon, platinum, tungsten or silicon oxide.
